(19) United States
(12) Patent Application Publication
(10) Pub. No.: US 2007/0164736 A1
(43) Pub. Date: Jul. 19, 2007

(54) Magnetometer with open magnetic circuit and production method thereof

(75) Inventors: Helene Joisten, Grenoble (FR); Robert Cuchet, Le Village (FR)

Correspondence Address: OBLON, SPIVAK, MCCLELLAND, MAIER & NEUSTADT, P.C., 1940 DUKE STREET, ALEXANDRIA, VA, 22314, US

(73) Assignee: COMMISSARIAT A L'ENERGIE ATOMIQUE, Paris 15eme (FR)

(21) Appl. No.: 10/574,702

(22) PCT Filed: Oct. 5, 2004
(86) PCT No.: PCT/FR04/50484

§ 371 Date: Dec. 12, 2006

(30) Foreign Application Priority Data
Oct. 6, 2003 (FR) 0311681

(51) Int. Cl. G01R 33/04

(52) U.S. Cl. 324/253

(57) ABSTRACT

The invention relates to an improved micro-fluxgate magnetometer capable of reducing noise phenomena that can occur when measuring a magnetic field, in a simple manner, and a method for manufacturing such a magnetometer in thin layers.

### TECHNICAL DOMAIN

This invention relates to the domain of magnetometers or magnetic sensors.

In particular, it relates to a microelectronic device comprising an integrated fluxgate magnetometer or improved micro-fluxgate magnetometer and a method for manufacturing such a device.

An integrated magnetometer means a circuit made of thin layers used for measuring the magnetic field or a variation of the magnetic field.

### STATE OF PRIOR ART

A magnetometer and particularly a fluxgate magnetometer usually comprises a magnetic circuit comprising connections and a magnetic core, for example based on an amorphous material or a magnetic alloy, for example Permalloy. It usually also comprises an excitation circuit of the core. This excitation circuit preferably comprises at least one excitation winding exciting the magnetic circuit and a detection circuit comprising at least one reception winding or detection winding that makes the measurement. These elements operate in cooperation. In the case of a fluxgate magnetometer, the excitation circuit applies excites the core with an alternating excitation.

An “open” magnetic circuit is typically in the form of an arrangement of one or several branches or segments with various shapes based on magnetic material and comprising ends that may or may not be connected to each other.

The branches of the core of an open magnetic circuit are usually arranged so that they do not create a loop or closed contour. An open magnetic core comprises at least two ends that are not connected to each other.

Micro-fluxgate magnetometers may be used in microelectronics and may for example be incorporated into integrated circuits. They are then made using thin layer manufacturing techniques. Fluxgate magnetometers formed in thin layers may be less than one millimetre in size, with thin layers possibly of the order of a micrometer thick, in which case they are called micro-fluxgate magnetometers.

Micro-fluxgate magnetometers are used in measurements of small or even very small magnetic fields. They can thus be used for example to measure very small variations in the earth's magnetic field. Thus, the sensitivity of some micro-fluxgate magnetometers is of the order of a few nanoteslas or even of the order of one picotesla, depending on the dimensions of the magnetometer. Furthermore, it is continuously desirable to be able to increase the sensitivity of magnetometers and particularly micro-fluxgate magnetometers, but non-negligible noise phenomena appear as the order of magnitude of measurements of magnetic fields or magnetic field fluctuations reduces.

In particular, another type of noise appears specifically in micro-fluxgate magnetometers comprising an open magnetic circuit. This type of noise results particularly from the fact that in this type of device, the dimensions of the magnetic core are of the same order of magnitude as the dimensions of the magnetic domains.

When small field magnetic fields are being measured, the noise level may make measurements very difficult. Furthermore, noise phenomena are uncertain. For example, they may originate from relative hysteresis of the magnetic material included in the magnetic core, or the unforeseeable movement of magnetic domains in the thin layers.

One known method according to prior art for resisting noise phenomena consists of applying an additional magnetic field orthogonal to the measured magnetic field, which improves polarisation of the magnetic circuit without having any influence on the measurement made by the detection circuit. However, this method does have several disadvantages. It requires an additional circuit in the magnetometer to apply the additional magnetic field. This complicates integration and the method for making the magnetic sensor.

Furthermore, the additional circuit significantly increases the current consumption of the magnetometer, which may be unfortunate when magnetometers are integrated into very small microelectronic devices.

### PRESENTATION OF THE INVENTION

This invention reduces noise phenomena in magnetometers or micro-fluxgate magnetic sensors provided with an “open” magnetic circuit. It proposes an improved microelectronic device comprising a micro-fluxgate magnetometer that includes means for reducing noise phenomena and a method for making such a micro-fluxgate magnetometer. The most advantageous form of the invention is simpler to make than the solution according to prior art mentioned above, and it also enables space saving and induces little or no additional current consumption.

The invention uses a micro-fluxgate magnetometer or an integrated fluxgate magnetometer comprising:

an open magnetic circuit comprising at least one magnetic core based on a magnetic material with at least two free ends,

one or several detection windings wound around the core,

one or several excitation windings wound around the magnetic core, so as to enable the entire magnetic material to reach saturation.

The excitation windings may be arranged so as to induce a uniform core excitation magnetic field.

According to one embodiment, the excitation windings may be arranged so that at least one of the excitation windings projects beyond at least one of the free ends of the core.

The invention also includes a micro-fluxgate magnetometer or an integrated fluxgate magnetometer comprising:

an open magnetic circuit comprising at least one magnetic core provided with at least two free ends,

one or several detection windings wound around the core;

one or several excitation windings wound around the magnetic core, at least one of the excitation windings projecting from at least one of the free ends of the core.

The excitation and detection windings may be separate or they may be coincident in some cases.

The projection of the excitation winding from at least one of the ends of the core provides a means of limiting noise phenomena in the magnetometer. Noise phenomena originate partly from unsaturated magnetic zones in the magnetic circuit. Thus, the projection of the excitation winding saturates the ends of the magnetic core. When this projection is applicable to all ends of the core, the presence of unsaturated magnetic areas in the magnetometer is minimised. Furthermore, the invention is applicable to an open magnetic circuit, in other words the branches of the magnetic core do not form a closed contour or a loop but have at least two free ends, in other words ends not connected to each other.

The invention relates to integrated fluxgate magnetometers or micro-fluxgate magnetometers, in other words magnetometers that are included in an integrated circuit or in a chip. The invention also relates to microelectronic devices for measuring integrated fluxgate fields or magnetic field variations comprising an open magnetic circuit.

The magnetometer according to the invention may also comprise a current generator coupled to excitation windings to output the excitation current, and measurement means coupled to the detection windings.

According to another particular feature of the magnetometer, one of the excitation windings may comprise at least one turn projecting entirely beyond at least one of the ends of the magnetic core.

According to another particular feature of the magnetometer according to the invention, the width of the excitation windings may be l_{be}, one of the excitation windings can then project from at least one of the free ends of the magnetic core by a projecting length D greater than ( 1/10) l_{be}. This projecting length D corresponds approximately to the limit of the area in which the magnetic field remains constant and is not reduced by edge effects. Fixing a projection length D greater than ( 1/10) l_{be} further limits instabilities originating from the magnetic core.

To completely saturate the magnetic core, it may be useful for excitation windings wound around the core to cover the core completely and for their accumulated total length to be than the accumulated total length of the branches of the core. Thus, according to one particular feature of the invention, the total length of the magnetic core is L_{noytot} corresponding to the sum of all lengths of branches of the core, and the total length of the excitation windings is L_{betot}, corresponding to the sum of the lengths of all excitation windings, where L_{betot} may be greater than L_{noytot}.

According to another particular feature of the magnetometer according to the invention, the excitation windings and the detection windings may be at least partially interlaced. This configuration is not compulsory but it can result in a space saving in the magnetometer. The detection and excitation windings are usually interlaced except at the ends and beyond the ends of the magnetic core. The excitation and detection windings can also be made adjacent around the core.

According to another particular feature of the micro-fluxgate magnetometer according to the invention, it may also comprise a compensation circuit capable of applying a magnetic field compensating a magnetic field to be measured, for example a continuous or low frequency magnetic field.

The compensation circuit may be formed from connections and compensation windings, also called reaction windings wound around the magnetic core. These compensation windings may be used to apply a magnetic field compensating a continuous or low frequency magnetic field to be measured.

The compensation windings may be separate or they may be coincident with the detection windings.

The micro-fluxgate magnetometer according to the invention may be made in thin layers and integrated into microelectronic chips or devices. A magnetometer with a size of the order of less than one micrometer could be applicable to a large number of industrial fields, and for example it may be used in applications in the aerospace or medical field.

Finally, the invention relates to a method for manufacturing the micro-fluxgate magnetometer, including the formation of a magnetic core provided with at least two free ends, and the formation of one or several detection windings wound around the core and one or several excitation windings wound around the magnetic core, one of the excitation windings projecting from at least one of the ends of the core.

The method according to the invention may include a first sub step consisting of forming lower portions of the said detection and excitation windings before the core formation step, and a second sub step consisting of forming upper portions of the said detection and excitation windings after the core formation step.

The second sub step may be done after a step to form vertical connectors used to connect the lower and upper portions of the said detection and excitation windings.

The core formation step may be done on a dielectric layer. According to one particular feature of the method according to the invention, the said dielectric layer is made plane before the core formation step. This flattening step prior to formation of the core can result in a plane magnetic core, therefore less likely to be the source of noise phenomena.

### BRIEF DESCRIPTION OF THE DRAWINGS

This invention will be better understood after reading the description of example embodiments given purely for information purposes and in no way limitatively, with reference to the appended figures, wherein:

FIGS. 1 to 3 show different variants of magnetometers or micro-fluxgate magnetic field measurement devices according to the invention, FIG. 4 shows a sectional view of part of the example micro-fluxgate magnetometer according to the invention illustrated in FIG. 1. The section is made along an x′x axis represented in FIG. 1,

FIGS. 5A-5G show different steps in an example method of manufacturing a micro-fluxgate magnetometer according to the invention.

Identical, similar or equivalent parts in the different figures are marked with the same numbers so as to facilitate looking at different figures.

The different parts shown in the figures are not necessarily at a uniform scale, to make the figures more readable.

### DETAILED PRESENTATION OF PARTICULAR EMBODIMENTS

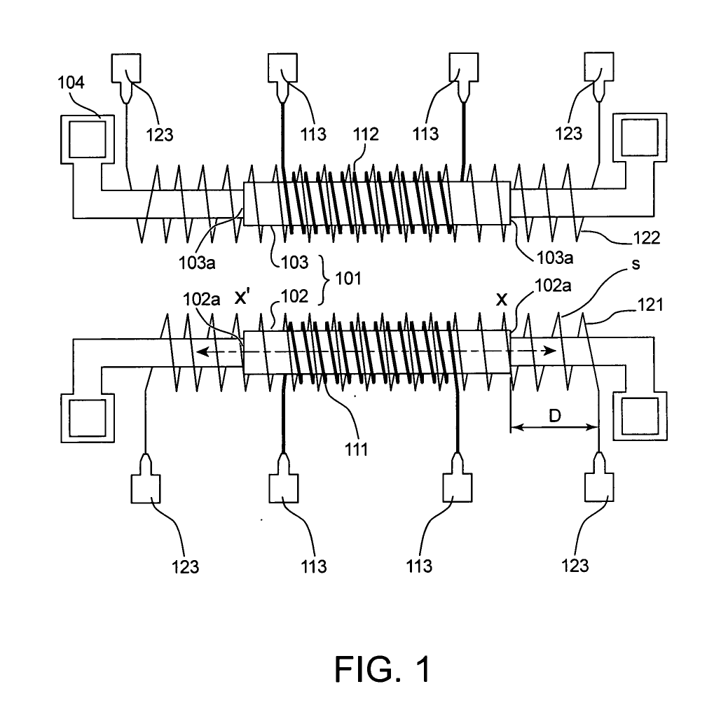

FIG. 1 shows an example device according to the invention formed from a magnetometer or a micro-fluxgate magnetic sensor or an integrated fluxgate sensor, in other words a fluxgate magnetometer included in a microelectronic device such as a MEMS (Microelectromechanical system) or a chip.

The magnetometer comprises a magnetic circuit comprising connections 104 and a magnetic core 101 that in this example is formed from two branches 102 and 103 that are straight and approximately orthogonal and parallel to each other.

The invention is applicable to magnetic cores with other shapes and that may comprise one or several branches arranged differently from the branches 102 and 103 illustrated in FIG. 1. However, the invention relates to an “open” magnetic circuit in which the branches do not make a loop or closed contour. Thus, the magnetic core 101 has several free ends, in other words unconnected ends, denoted 102a, 103a in FIG. 1.

The magnetic core 101 may be made based on any type of magnetic material such as an amorphous magnetic material, a soft magnetic material, an alloy for example such as an iron and nickel based alloy, or an iron and cobalt based alloy, or an iron, nickel and indium based alloy. Furthermore, the magnetic core 101 may be made of a stack of several layers of different materials.

The magnetometer also comprises an excitation circuit comprising connections marked 123, and a first excitation winding and a second excitation winding denoted 121 and 122 respectively and wound around branches 102 and 103 respectively of the core 101 of the magnetic circuit. The excitation windings 121 and 122 are connected to a generator (not shown) that outputs an alternating signal to the windings and arranged so as to create a magnetic excitation field in the magnetic core 101.

The width of each excitation winding 121, 122 is l_{be} and its length is L_{be}. They surround the magnetic core over its entire length such that several turns S of excitation windings project beyond the free ends 102a, 103a of the core 101.

The fact that at least one of the ends 102a or 103a of the magnetic core 101 is completely inside one of the excitation windings 121 or 122 makes it possible to saturate the magnetic core 101 by using a uniform excitation field.

The excitation winding 121 can project beyond the ends of the core 101 by a projecting length denoted D and greater than ( 1/10)l_{be}. Thus, the magnetic core 101 saturated as far as its ends is within an area with a constant magnetic field.

The total length L_{noytot} of the magnetic core 101 is equal to the accumulated length of its branches 102 and 103. The length of each of the excitation windings 121 and 122 is L_{be}, which means that the accumulated length of the excitation windings L_{betot} is equal to 2L_{be}.

According to one particular feature of the invention, L_{betot} can be greater than L_{noytot}, in other words the winding can cover the entire core 101 and it can thus project beyond all the ends of the core 101. Thus, all the ends of the core 101 can be saturated and noise phenomena that can originate from some unsaturated parts of the core are attenuated.

The micro-fluxgate magnetometer according to the invention also comprises a detection circuit comprising connections denoted 113 and a first and a second detection winding denoted 111 and 112 respectively and each wound around part of the branches 102 and 103 of the core 101 of the magnetic circuit.

The first and second detection windings 111 and 112 in this example are interlaced with the first and second excitation windings 121 and 122 respectively.

Note that the number of detection and excitation windings of the magnetometer according to the invention, and the layout of the detection windings 111 and 112 are in no way limited to what is illustrated in FIG. 1. Thus, the invention may comprise one or several excitation windings, one or several detection windings that may or may not be interlaced with the detection windings.

Furthermore, the number of turns of detection windings 111, 112 and excitation windings 121, 122 and the winding density (number of turns over a unit length) are not shown at full scale in FIG. 1, since other winding densities and numbers of turns are possible.

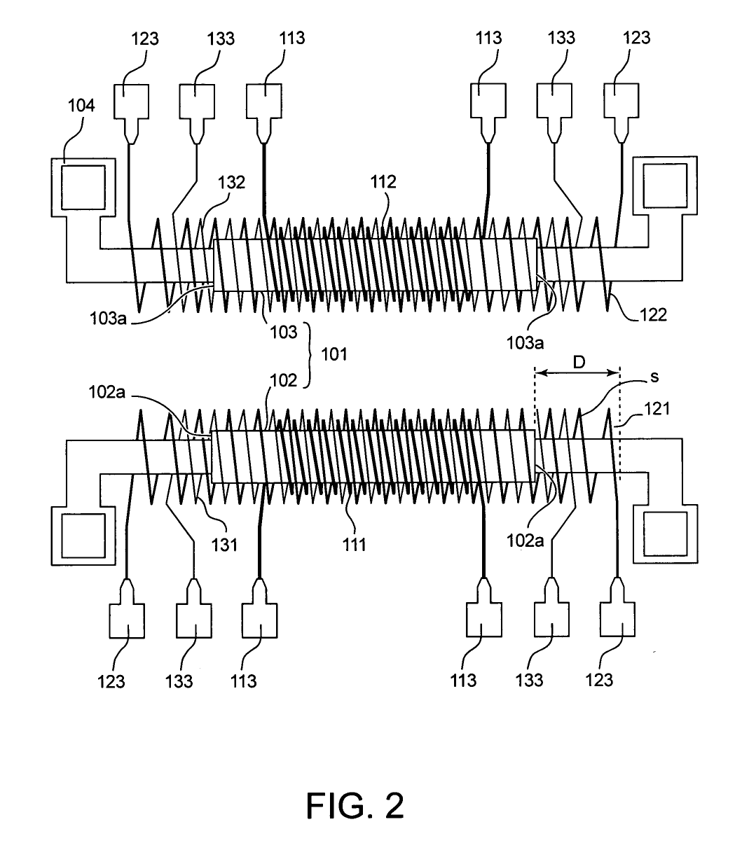

FIG. 2 shows a second example micro-fluxgate magnetometer according to the invention that is different from that in the example illustrated in FIG. 1 in that the magnetometer also comprises a compensation circuit comprising connections denoted 133 and two reaction windings or compensation windings 131 and 132 wound around branches 102 and 103 respectively of the core. The compensation windings 131 and 132 can be interlaced with the excitation windings 121 and 122. These reaction windings 131 and 132 can be used to apply a magnetic field compensating a continuous or low frequency magnetic field to be measured.

When the magnetometer does not comprise a reaction winding, the detection windings 111 and 112 can act as compensation windings 131 and 132.

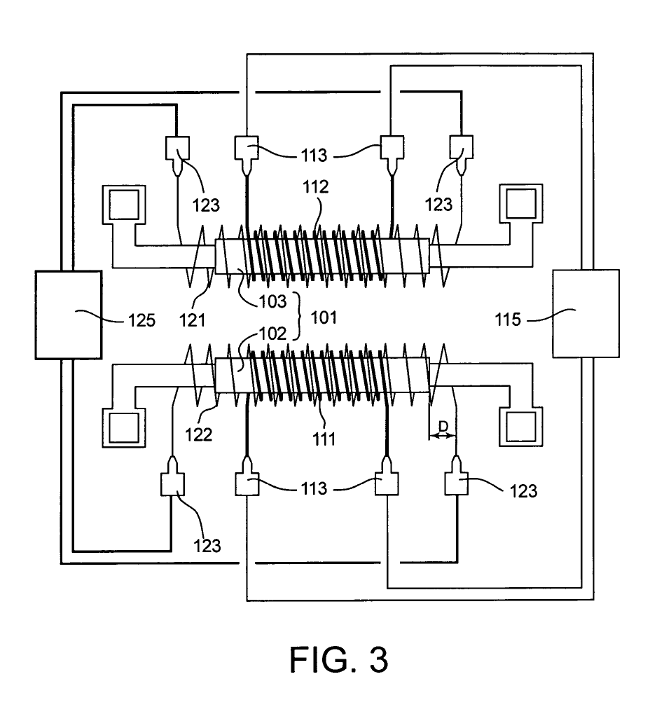

FIG. 3 shows another example micro-fluxgate magnetometer according to the invention provided with an excitation circuit comprising an alternating current generator 125 connected to excitation windings 121 and 122 through connections 123. The detection circuit also comprises a measurement means 115 connected to the detection windings 111 and 112 through connections 113.

The magnetometer according to the invention may be made from thin layers. FIG. 4 shows a sectional view along the x′x axis of part of the magnetometer illustrated in FIG. 1.

The integrated fluxgate magnetometer or the micro-fluxgate magnetometer is made from a stack of thin layers. A lower insulating layer 401, for example based on an insulating material such as SiO₂ or a photosensitive polymer for example with a thickness of between 1 and 10 micrometers, for example equal to 5 micrometers, is supported for example on a silicon-based substrate 400. The lower insulating layer 401 comprises lower portions 402 of excitation windings 121 and detection windings 111. These lower portions 402 of windings are in the form of conducting lines extending in a direction approximately orthogonal to x′x and parallel to a main plane of the substrate. Furthermore, the shape of the lower portions 402 of the windings is also rectangular in this example. Furthermore, the lower portions 402 of windings may be made based on metallic materials, for example such as copper, aluminium, gold, etc.

A first dielectric layer 403 is supported on the lower insulating layer 401, for example based on SiO₂ with a thickness for example of between 1 and 10 micrometers, for example equal to 3 micrometers. This first dielectric layer 403 is inserted between the lower portions 402 of windings 121 and 111 located below it and a magnetic core 101 contained in a dielectric layer 404 above it. Thus, the magnetic core 101 and the lower portions 402 of the windings are isolated. The magnetic core 101 extends in a direction parallel to the x′x axis over a length denoted L_{noy}. It can be formed based on a magnetic material such as a soft magnetic material, an amorphous magnetic material, or an alloy for example such as an iron and nickel based alloy. The core can be formed from a single layer or a stack of several layers of different materials and its thickness may for example be between 500 nanometers and 5 micrometers, for example approximately 1 micrometer.

There is a second dielectric layer 405 based for example on SiO2 with a thickness of between 1 and 10 micrometers, for example equal to 3 micrometers, on the layer 404 containing the core 101.

The second dielectric layer 405 acts as insulation between the core 101 located below it and the upper portions 407 of the windings 111 and 121 located above it inserted in a layer 406 located on the second dielectric layer 405.

These upper portions 407 of windings are in the form of conducting lines that extend in a direction orthogonal to x′x and parallel to a main plane of the substrate. The upper portions 407 of the windings are rectangular. The upper portions 407 of the windings may be made based on metallic materials, for example such as copper, aluminium, gold, etc.

The layers 403, 404 and 405 are pierced so that vertical connectors 408 can be fitted in them, for example based on metal joining the lower portions 402 and the upper portions 407 of the windings 111 and 121.

The lower portions 402 and the upper portions 407 of the windings 111 and 121 connected by vertical connectors 408 produce rectangular turns.

The excitation winding 121 extends in a direction parallel to the direction of the core 101 over a length L_{be} greater than the length L_{noy} of the core.

Thus, the excitation winding 121 is wound around the core 101 and it covers the entire core. Furthermore, the excitation winding 121 projects beyond the ends 102a of the core 101 by a projecting length D at one end and a projecting length D′ not equal to D at the other end. This configuration in which the excitation winding 121 projects beyond the ends of the core 101 improves saturation of the magnetic circuit and thus limits noise phenomena in the magnetometer.

Connection pins 409, for example based on a metallic material, are also inserted in the layer 406 and for example are used to circulate current from external circuits to the different windings or from the different windings to external circuits.

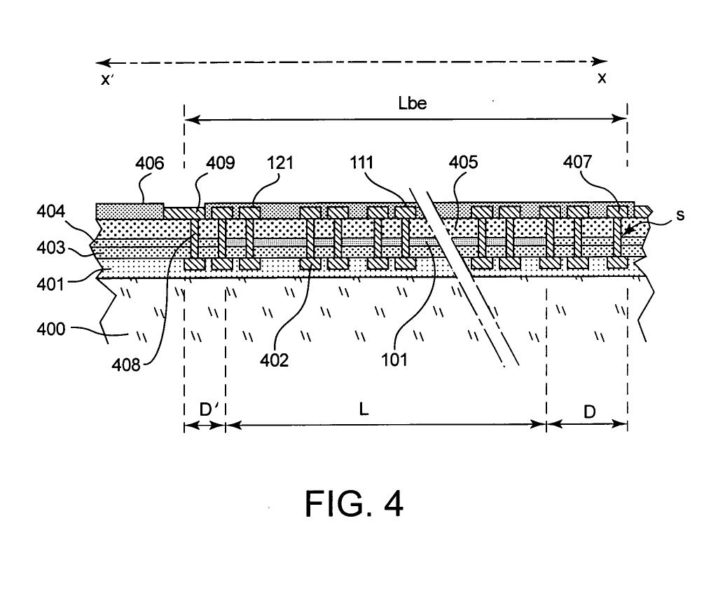

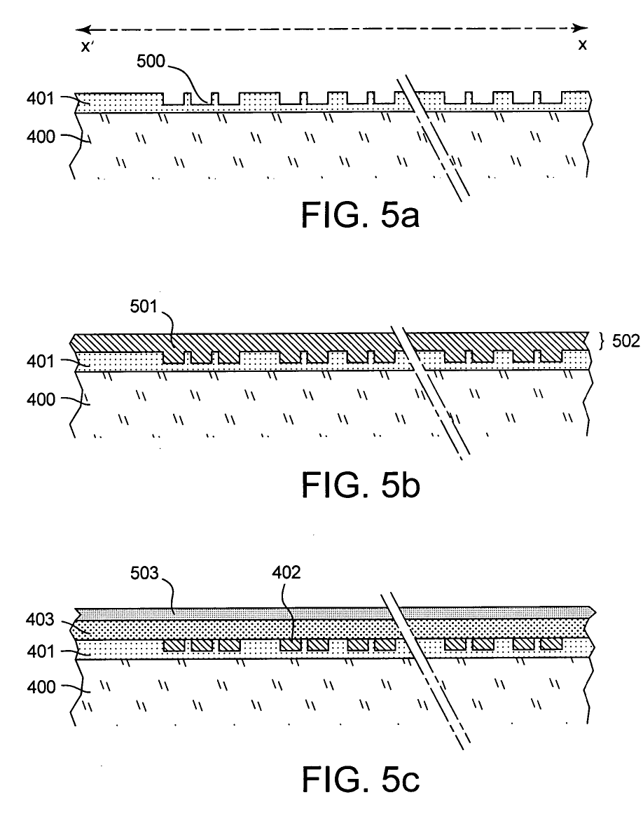

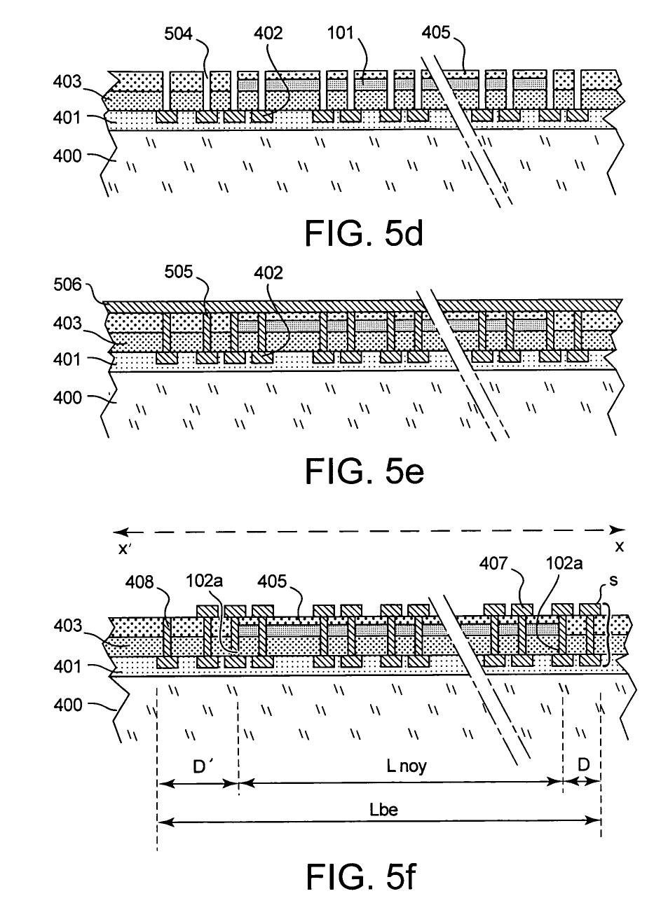

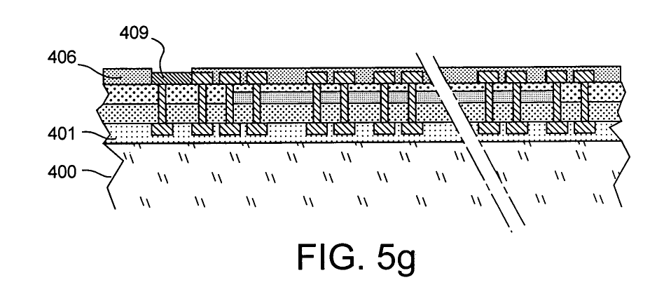

The device shown in FIG. 4 can be obtained using a manufacturing method, an example of which is illustrated in FIGS. 5A to 5H.

The first step in this method consists of forming the lower insulating layer 401, for example between 2 and 5 micrometers thick, for example by chemical vapour phase deposition of an insulating material or by growth of an oxide such as SiO₂ on the substrate 400. Several adjacent trenches 500 are then formed in the insulating layer 401 extending in a direction parallel to a main plane of the substrate 400 and orthogonal to the x′x axis (FIG. 5A). For example, the trenches 500 may be between 1 and 3 micrometers deep. They can be made using conventional photolithography methods, and followed by etching of the insulating layer 401.

The trenches are then filled with a conducting material 501, for example copper based such that the conducting material fills the trenches 500 and a thickness 502 of the conducting material projects beyond the surface of the insulating layer 401. For example, filling may be done by electrolysis of copper or by a deposition such as a chemical vapour phase deposition (FIG. 5B).

The surface thickness 502 of the conducting material 501 is then polished until the surface of the insulating layer 401 is reached, for example using the CMP (chemical-mechanical polishing) method. The trenches 500 filled by the conducting material 501, for example based on copper, form the lower portions 402 of the windings 111 and 121 previously illustrated in FIG. 4.

The next step is to make a deposition with a thickness of between 1 and 8 micrometers, for example using the chemical vapour phase deposition method for the first dielectric layer 403, for example based on SiO₂. The next step is polishing such as a mechanical-chemical polishing (CMP) of the first dielectric layer 403.

The next step is to form the magnetic core 101 on the first dielectric layer 403, for example using a chemical vapour phase deposition method or cathode sputtering of a layer or a stack 503 of several layers based on magnetic material. The layer or the stack 503 may be between 100 nanometers and 5 micrometers thick, for example 1 micrometer thick. The layer 503 may be based on a magnetic material such as a soft magnetic material, or an amorphous magnetic material. It may comprise an alloy for example such as an iron and nickel based alloy or a “permalloy” alloy, or an iron and cobalt based alloy, or an iron, nickel and indium based alloy. The layer 503 may comprise any type of material that can form a magnetic core. It is preferably as plane as possible, because lack of planeness of the magnetic core can induce additional magnetic noise into the magnetometer. Thus, the layer 503 may be made at least partly plane in a flattening step of the dielectric layer 403 mentioned and described above. The layer 503 is then etched so as to form the magnetic core 101 in the form of branches with length L_{noy} extending along a direction parallel to the x′x axis. A second dielectric layer 405, for example with a thickness of between 1 and 5 micrometers, for example equal to 2 micrometers, is then deposited on the magnetic core 101 and covers it. In this example embodiment, the core 101 is integrated into the layer 403. The dielectric 404 in FIG. 4 then corresponds to part of the layer 403 in this particular example.

Vertical orifices 504 are then made, for example by etching the second dielectric layer 405 containing the core 101 and the first dielectric layer 403. The vertical orifices 504 reach the lower portions 402 of the windings (FIG. 5D).

These vertical orifices 504 are then filled by electrolysis or by deposition of a conducting material 505, for example based on copper, aluminium, etc. The filled vertical orifices 504 form vertical metallic connectors 408 orthogonal to the lower portions 402 of the windings and the magnetic core 101. After formation of the connectors 408, a thickness for example equal to between 1 and 5 micrometers of the metallic material 506 based on copper, gold or aluminium is deposited. According to one variant, the thickness of metallic material 506 is obtained by prolonging the electrolysis or deposition step of the conducting material 505 used to fill the vertical orifices 504 (FIG. 5E).

The next step is to make the upper portions 407 of the windings by etching the metallic material such that the upper portions of the windings are connected by the vertical connection 408 to the lower portions 402 to form turns s of windings (FIG. 5F). Among the windings thus formed, the excitation winding denoted 121 is wound around the core 101, such that it surrounds and projects beyond the ends denoted 102a of the core 101 by a projecting length D.

Finally, the layer 406 is made for example by deposition of an insulating material 505 surrounding the upper portions 407 of the windings. This layer 406 is then perforated so that connection pins 409 can be inserted in it.

1. Micro-fluxgate magnetometer comprising:
an open magnetic circuit comprising at least one magnetic core based on a magnetic material with at least two free ends,
one or several detection windings wound around the core,
one or several excitation windings wound around the magnetic core, so as to enable the entire magnetic material to reach saturation.

2. Micro-fluxgate magnetometer according to claim 1, the excitation windings being arranged so as to induce a uniform core excitation magnetic field.

3. Micro-fluxgate magnetometer according to claim 1 or 2, at least one of the excitation windings projecting beyond at least one of the free ends of the core.

4. Micro-fluxgate magnetometer according to claim 3, one of the excitation windings comprising at least one turn projecting entirely beyond at least one of the ends of the magnetic core.

5. Micro-fluxgate magnetometer according to claim 3, in which the width of the excitation windings is l_{be}, at least one of the excitation windings projecting from at least one of the free ends of the magnetic core by a projecting length D greater than ( 1/10) l_{be}.

6. Micro-fluxgate magnetometer according to claim 3 in which the total length of the magnetic core is L_{noytot} and the total length of the excitation windings is L_{betot}, where L_{betot} is greater than L_{noytot}.

7. Micro-fluxgate magnetometer according to claim 1 or 2 or 3, the excitation windings and the detection windings being interlaced.

8. Micro-fluxgate magnetometer according to claim 3, the magnetometer also comprising a compensation circuit capable of applying a magnetic field compensating a magnetic field to be measured.

9. Micro-fluxgate magnetometer according to claim 3, the magnetometer also comprising a current generator coupled to the excitation winding(s) and measurement means coupled to the detection winding(s).

10. Micro-fluxgate magnetometer according to claim 3, the magnetometer being formed from a stack of thin layers.
